(19) United States
(12) Patent Application Publication
(10) Pub. No.: US 2026/0250498 A1
(43) Pub. Date: Aug. 27, 2026

(54) RESIN COMPOSITION, PREPREG, RESIN FILM, METAL-CLAD LAMINATE, PRINTED WIRING BOARD, SEMICONDUCTOR PACKAGE, AND ACENAPHTHYLENE HOMOPOLYMER

(71) Applicant: RESONAC CORPORATION, Tokyo (JP)

(72) Inventors: Yuji MATO, Tokyo (JP); Shinichiro ABE, Tokyo (JP); Yusuke SERA, Tokyo (JP); Ai YOKOKURA, Tokyo (JP)

(21) Appl. No.: 18/860,671

(22) PCT Filed: Mar. 26, 2024
(86) PCT No.: PCT/JP2024/011892

§ 371 Date: Oct. 27, 2024

(30) Foreign Application Priority Data
Apr. 10, 2023 (JP) 2023-063536

(51) Int. Cl. C08L 25/08; C08J 5/18; C08J 5/24; H10W 70/695

(52) U.S. Cl. CPC C08L 25/08; C08J 5/18; C08J 5/244; H10W 70/695; C08J 2325/08; C08J 2465/00; C08L 2203/16; C08L 2203/20

(57) ABSTRACT

Provided is a resin composition including: an (A) thermosetting resin; and a (B) acenaphthylene polymer with a number average molecular weight of 1,000 or more.

### TECHNICAL FIELD

The present disclosure relates to a resin composition, a prepreg, a resin film, a metal-clad laminate, a printed wiring board, a semiconductor package, and an acenaphthylene homopolymer.

### BACKGROUND ART

Metal-clad laminates represented by copper-clad laminates, prepregs usable for metal-clad laminates, and semiconductor packages using metal-clad laminates are used in various electronic devices like portable communication devices such as smartphones, personal computers, industrial computers, servers, large servers, routers, and portable base stations. They are also used in electronic devices mounted in household appliances and automobiles. From thereamong, due to the spread of 5G, demand for electronic communication devices to process a large amount of data at a high speed is increasing.

When an electronic device processes a large amount of data at a high speed, a substrate material or the like with a small transmission loss in a high frequency range is required for the device, and a material with a low permittivity and a low dielectric loss tangent is required.

In addition, this kind of substrate material is required to have flame retardancy, and the use of a phosphorus-based flame retardant or the like in a resin composition has been studied (for example, Patent Literature 1).

### CITATION LIST

### Patent Literature

Patent Literature 1: JP 2004-315725 A

### SUMMARY OF THE INVENTION

### Problems to be Solved by the Invention

An object of the present disclosure is to provide a resin composition with low sublimability, used for providing a product with excellent dielectric properties and flame retardancy. An object of the present disclosure is also to provide a prepreg, a resin film, a metal-clad laminate, a printed wiring board, and a semiconductor package formed using the resin composition, and an acenaphthylene homopolymer.

### Means for Solving the Problem

Examples of embodiments will be listed below. The present invention is not limited to the following embodiments.

One embodiment relates to a resin composition including: an (A) thermosetting resin; and a (B) acenaphthylene polymer with a number average molecular weight of 1,000 or more.

Another embodiment relates to a prepreg formed using the resin composition.

Another embodiment relates to a resin film formed using the resin composition.

Another embodiment relates to a metal-clad laminate including: a metal foil, and a cured product of the resin composition.

Another embodiment relates to a metal-clad laminate formed using the prepreg and a metal foil.

Another embodiment relates to a printed wiring board including: a cured product of the resin composition.

Another embodiment relates to a semiconductor package including: the printed wiring board, and a semiconductor element.

Another embodiment relates to an acenaphthylene homopolymer having a number average molecular weight of 1,000 or more.

### Advantageous Effects of the Invention

The present disclosure can provide a resin composition with low sublimability, used for providing a product with excellent dielectric properties and flame retardancy. The present disclosure can also provide a prepreg, a resin film, a metal-clad laminate, a printed wiring board, and a semiconductor package formed using the resin composition, and an acenaphthylene homopolymer.

### BRIEF DESCRIPTION OF THE DRAWINGS

FIG. 1 is a schematic diagram schematically illustrating an example of a metal-clad laminate of an embodiment.

### EMBODIMENTS FOR CARRYING OUT THE INVENTION

Embodiments of the present invention will be described below in detail. The present invention is not limited to the following embodiments.

In the present disclosure, a numerical range indicated using “to” indicates a range including numerical values described before and after “to” as minimum and maximum values. In numerical ranges described in a stepwise manner in the present disclosure, an upper or lower limit of a certain numerical range may be replaced with an upper or lower limit of another numerical range. In addition, upper or lower limits of numerical ranges described in the present disclosure may be replaced with values shown in Examples.

In the present disclosure, each component may contain one or two or more substances corresponding thereto, unless otherwise specified.

In the present disclosure, when a plurality of substances corresponding to each component are present in a resin composition, the amount of each component in the resin composition means the total amount of the plurality of substances present in the resin composition, unless otherwise specified.

In the present disclosure, the weight average molecular weight (Mw) and the number average molecular weight (Mn) are measured values according to the following measurement methods, unless otherwise specified.

The weight average molecular weight and the number average molecular weight are obtained through measurement by gel permeation chromatography (GPC), and conversion with the use of a calibration curve of standard polystyrene. The calibration curve is approximated by a cubic equation using standard polystyrene: TSKstandard POLYSTYRENE (Type; A-2500, A-5000, F-20, and F-80) (manufactured by Tosoh Corporation, product name). The conditions of GPC are as follows.

System: High Performance GPC System “HLC-8320GPC” (Tosoh Corporation, product name)

Detector: UV Detector “UV-8320” (Tosoh Corporation, product name)

Column: guard column; TSKgel guardcolumn Super (HZ)-M+, column; TSKgel SuperMultipore HZ-M (two columns), reference column; TSKgel SuperH-RC (two columns) (all manufactured by Tosoh Corporation, product names)

Column sizes: 4.6 mm×20 mm (guard column), 4.6 mm×150 mm (column), 6.0 mm×150 mm (reference column)

Eluent: tetrahydrofuran

Sample concentration: 10 mg/l mL

Injection volume: 20 μL or 2 μL

Flow rate: 0.35 mL/minute

Measurement temperature: 40° C.

### [Resin Composition]

A resin composition of an embodiment of the present disclosure contains an (A) thermosetting resin and a (B) acenaphthylene polymer with a number average molecular weight of 1,000 or more. The “(A) thermosetting resin” may be referred to as an “(A) component” below. The “(B) acenaphthylene polymer with a number average molecular weight of 1,000 or more” may be referred to as a “(B) acenaphthylene polymer” or “(B) component”.

By using the resin composition, it is possible to provide a product with excellent dielectric properties and high flame retardancy. In addition, the resin composition has low sublimability, and is less likely to be a cause of contamination of equipment such as a drying furnace. Although not constrained by any particular theory, the reasons for this are thought to include the following. Acenaphthylene may enable favorable dielectric properties due to having a skeleton with a low polarity. Further, the present inventors found that acenaphthylene has excellent flame retardancy. This is presumed to be because a skeleton of acenaphthylene is polycyclic aromatic, and therefore the heat of combustion is small. Meanwhile, acenaphthylene has high sublimability, and when acenaphthylene is sublimated by heating, acenaphthylene may be a cause of contamination of equipment such as a drying furnace. It is presumed that the use of an acenaphthylene polymer with a number average molecular weight of 1,000 or more, which is a polymerized form of acenaphthylene, in the resin composition makes it possible to achieve low sublimability, in addition to favorable dielectric properties and high flame retardancy.

### <(A) Thermosetting Resin>

There are no particular limitations on the (A) thermosetting resin, and examples of the (A) thermosetting resin include an epoxy resin, a maleimide compound, a phenolic resin, a modified polyphenylene ether resin, a polyimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, a melamine resin, and a compound with a vinylbenzyl group. When the thermosetting resin is heated in the presence of a polymerization initiator or the like when necessary, polymerization and/or a curing reaction of the thermosetting resin can proceed. A compound with a vinylbenzyl group and a maleimide compound, which will be described later, may be a monomer, an oligomer, a prepolymer, or the like, and these can also be used as the (A) thermosetting resin, for example.

As the (A) component, one of them may be used alone, or a combination of two or more may be used.

The epoxy resin preferably has two or more epoxy groups in one molecule. Examples of the epoxy resin include a glycidyl ether-type epoxy resin, a glycidyl amine-type epoxy resin, and a glycidyl ester-type epoxy resin.

In each of the above types of epoxy resins, an epoxy resin can be further classified into a bisphenol type epoxy resin, an alicyclic epoxy resin, an aliphatic chain epoxy resin, a novolac type epoxy resin, a stilbene type epoxy resin, a naphthalene skeleton-containing epoxy resin, a biphenyl type epoxy resin, a xylylene type epoxy resin, and a dihydroanthracene type epoxy resin. Examples of the bisphenol type epoxy resin include a bisphenol A type epoxy resin, a bisphenol F type epoxy resin, and a bisphenol S type epoxy resin. Examples of the alicyclic epoxy resin include a dicyclopentadiene type epoxy resin. Examples of the novolac type epoxy resin include a phenol novolac type epoxy resin, a cresol novolac type epoxy resin, a bisphenol A novolac type epoxy resin, a bisphenol F novolac type epoxy resin, a phenol aralkyl novolac type epoxy resin, and a biphenyl aralkyl novolac type epoxy resin. Examples of the naphthalene skeleton-containing epoxy resin include a naphthol novolac type epoxy resin and a naphthol aralkyl type epoxy resin.

One epoxy resin may be used alone, or a combination of two or more may be used.

Examples of the maleimide compound include a compound with one or more N-substituted maleimide groups and derivatives thereof. As the maleimide compound, it is possible to use at least one selected from the group consisting of a compound with two or more N-substituted maleimide groups, and derivatives thereof, for example.

Examples of the compound with one or more N-substituted maleimide groups include an aromatic maleimide compound, an aromatic bismaleimide compound, an aromatic polymaleimide compound, and an aliphatic maleimide compound. In the present disclosure, “aromatic maleimide compound” means a compound with an N-substituted maleimide group directly bonded to an aromatic ring. In the present disclosure, “aromatic bismaleimide compound” means a compound with two N-substituted maleimide groups directly bonded to an aromatic ring. In the present disclosure, “aromatic polymaleimide compound” means a compound with three or more N-substituted maleimide groups directly bonded to an aromatic ring. Further, in the present disclosure, “aliphatic maleimide compound” means a compound with an N-substituted maleimide group directly bonded to an aliphatic hydrocarbon.

Specific examples of the compound with one or more N-substituted maleimide groups include N,N′-ethylenebismaleimide, N,N′-hexamethylenebismaleimide, N,N′-(1,3-phenylene)bismaleimide, N,N′-[1,3-(2-methylphenylene)]bismaleimide, N,N′-[1,3-(4-methylphenylene)]bismaleimide, N,N′-(1,4-phenylene)bismaleimide, bis(4-maleimidophenyl)methane, bis(3-methyl-4-maleimidophenyl)methane, 3,3′-dimethyl-5,5′-diethyl-4,4′-diphenylmethane bismaleimide, bis(4-maleimidophenyl)ether, bis(4-maleimidophenyl)sulfone, bis(4-maleimidophenyl)sulfide, bis(4-maleimidophenyl)ketone, bis(4-maleimidocyclohexyl)methane, 1,4-bis(4-maleimidophenyl)cyclohexane, 1,4-bis(maleimidomethyl)cyclohexane, 1,4-bis(maleimidomethyl)benzene, 1,3-bis(4-maleimidophenoxy)benzene, 1,3-bis(3-maleimidophenoxy)benzene, bis[4-(3-maleimidophenoxy)phenyl]methane, bis[4-(4-maleimidophenoxy)phenyl]methane, 1,1-bis[4-(3-maleimidophenoxy)phenyl]ethane, 1,1-bis[4-(4-maleimidophenoxy)phenyl]ethane, 1,2-bis[4-(3-maleimidophenoxy)phenyl]ethane, 1,2-bis[4-(4-maleimidophenoxy)phenyl]ethane, 2,2-bis[4-(3-maleimidophenoxy)phenyl]propane, 2,2-bis[4-(4-maleimidophenoxy)phenyl]propane, 2,2-bis[4-(3-maleimidophenoxy)phenyl]butane, 2,2-bis[4-(4-maleimidophenoxy)phenyl]butane, 2,2-bis[4-(3-maleimidophenoxy)phenyl]-1,1,1,3,3,3-hexafluoropropane, 2,2-bis[4-(4-maleimidophenoxy)phenyl]-1,1,1,3,3,3-hexafluoropropane, 4,4-bis(3-maleimidophenoxy)biphenyl, 4,4-bis(4-maleimidophenoxy)biphenyl, bis[4-(3-maleimidophenoxy)phenyl]ketone, bis[4-(4-maleimidophenoxy)phenyl]ketone, bis(4-maleimidophenyl)disulfide, bis[4-(3-maleimidophenoxy)phenyl]sulfide, bis[4-(4-maleimidophenoxy)phenyl]sulfide, bis[4-(3-maleimidophenoxy)phenyl]sulfoxide, bis[4-(4-maleimidophenoxy)phenyl]sulfoxide, bis[4-(3-maleimidophenoxy)phenyl]sulfone, bis[4-(4-maleimidophenoxy)phenyl]sulfone, bis[4-(3-maleimidophenoxy)phenyl]ether, bis[4-(4-maleimidophenoxy)phenyl]ether, 1,4-bis[4-(4-maleimidophenoxy)-α,α-dimethylbenzyl]benzene, 1,3-bis[4-(4-maleimidophenoxy)-α,α-dimethylbenzyl]benzene, 1,4-bis[4-(3-maleimidophenoxy)-α,α-dimethylbenzyl]benzene, 1,3-bis[4-(3-maleimidophenoxy)-α,α-dimethylbenzyl]benzene, 1,4-bis[4-(4-maleimidophenoxy)-3,5-dimethyl-α,α-dimethylbenzyl]benzene, 1,3-bis[4-(4-maleimidophenoxy)-3,5-dimethyl-α,α-dimethylbenzyl]benzene, 1,4-bis[4-(3-maleimidophenoxy)-3,5-dimethyl-α,α-dimethylbenzyl]benzene, 1,3-bis[4-(3-maleimidophenoxy)-3,5-dimethyl-α,α-dimethylbenzyl]benzene, polyphenylmethanemaleimide, an aromatic bismaleimide compound having an indane skeleton, and a biphenylaralkyl-type maleimide compound.

An example of a derivative of the compound with one or more N-substituted maleimide groups is an aminomaleimide compound having a structural unit derived from the compound with one or more N-substituted maleimide groups described above, and a structural unit derived from a diamine compound.

An example of the structural unit derived from the compound with one or more N-substituted maleimide groups, included in the aminomaleimide compound, is a structural unit obtained by performing a Michael addition reaction between an amino group of the diamine compound, and at least one of one or more N-substituted maleimide groups of the compound.

The number of the structural units derived from the compound with one or more N-substituted maleimide groups, included in the aminomaleimide compound may be one or two or more.

An example of the structural unit derived from the diamine compound, included in the aminomaleimide compound, is a structural unit obtained by performing a Michael addition reaction between one or both of two amino groups of the diamine compound, and an N-substituted maleimide group of one or more N-substituted maleimide groups of the compound.

The number of the structural units derived from the diamine compound, included in the aminomaleimide compound, may be one or two or more.

Examples of the diamine compound include aromatic diamine compounds such as 4,4′-diaminodiphenylmethane, 3,3′-dimethyl-4,4′-diaminodiphenylmethane, 3,3′-diethyl-4,4′-diaminodiphenylmethane, 4,4′-diaminodiphenyl ether, 4,4′-diaminodiphenylsulfone, 3,3′-diaminodiphenylsulfone, 4,4′-diaminodiphenyl ketone, 4,4′-diaminobiphenyl, 3,3′-dimethyl-4,4′-diaminobiphenyl, 2,2′-dimethyl-4,4′-diaminobiphenyl, 3,3′-dihydroxybenzidine, 2,2-bis(3-amino-4-hydroxyphenyl)propane, 3,3′-dimethyl-5,5′-diethyl-4,4′-diaminodiphenylmethane, 2,2-bis(4-aminophenyl)propane, 2,2-bis[4-(4-aminophenoxy)phenyl]propane, 1,3-bis(3-aminophenoxy)benzene, 1,3-bis(4-aminophenoxy)benzene, 1,4-bis(4-aminophenoxy)benzene, 4,4′-bis(4-aminophenoxy)biphenyl, 1,3-bis[1-[4-(4-aminophenoxy)phenyl]-1-methylethyl]benzene, 1,4-bis[1-[4-(4-aminophenoxy)phenyl]-1-methylethyl]benzene, 4,4′-[1,3-phenylenebis(1-methylethylidene)]bisaniline, 4,4′-[1,4-phenylenebis(1-methylethylidene)]bisaniline, 3,3′-[1,3-phenylenebis(1-methylethylidene)]bisaniline, bis[4-(4-aminophenoxy)phenyl]sulfone, bis[4-(3-aminophenoxy)phenyl]sulfone, and 9,9-bis(4-aminophenyl)fluorine. Examples of the diamine compound further include a silicone compound with two primary amino groups. In the present disclosure, the “aromatic diamine compound” means a compound with two amino groups directly bonded to an aromatic ring.

One maleimide compound may be used alone, or a combination of two or more may be used.

The compound having a vinyl benzyl group (hereinafter, the compound may also be referred to as a “vinylbenzyl compound”) may have one or more vinylbenzyl groups. The vinylbenzyl compound may have two or more vinylbenzyl groups. The vinylbenzyl compound has one or more vinylbenzyl groups in one molecule, and by promoting a reaction of the vinylbenzyl groups intramolecularly or intermolecularly by heating or the like, it is possible to obtain a cured product.

One vinylbenzyl compound may be used alone, or a combination of two or more may be used.

The vinylbenzyl compound may be any of a monomer, an oligomer, and a prepolymer, and a combination of two or more of them may be contained in the resin composition.

When the vinylbenzyl compound is a monomer, the vinylbenzyl compound may be a compound in which one or more vinylbenzyl groups are introduced into a base compound. The oligomer may be a low polymerization degree compound obtained by polymerizing this monomer to have two or more units. The prepolymer may be a compound in which one or more vinyl benzyl groups are introduced into the resin backbone. The prepolymer may be a polymer of: a monomer with one or more vinylbenzyl groups, an oligomer with one or more vinylbenzyl groups, or a combination thereof. It is preferable that both the oligomer and the prepolymer contain unreacted vinylbenzyl groups to some extent, and that a curing reaction is started by heating or the like.

The number of vinylbenzyl groups of the monomer as the vinylbenzyl compound may be 1 or more, or 2 or more, or may be in a range from 2 to 4, or in a range from 2 to 3, for example.

It is sufficient if the oligomer, or the prepolymer, as the vinylbenzyl compound has one or more vinylbenzyl groups in a molecule. It is preferable that the number of vinylbenzyl groups contained in a monomer structural unit is 1 or 2 or more, and the number of vinylbenzyl groups contained in the monomer structural unit is in a range from 2 to 4, or in a range from 2 to 3.

A vinylbenzyl group in the vinylbenzyl compound may be any of an o-vinylbenzyl group, an m-vinylbenzyl group, and a p-vinylbenzyl group. When the vinylbenzyl compound has two or more vinylbenzyl groups in one molecule, the two or more vinylbenzyl groups may be the same isomer, or different from each other. From the viewpoint of dielectric properties, it is preferable that the vinylbenzyl compound has at least one p-vinylbenzyl group in one molecule.

The amount of p-vinylbenzyl groups in one molecule of the vinylbenzyl compound may be in a range from 10% by mass to 100% by mass, in a range from 20% by mass to 80% by mass, in a range from 30% by mass to 70% by mass, or in a range from 40% by mass to 60% by mass, relative to the total mass of all vinylbenzyl groups.

The vinylbenzyl compound may have one or two or more vinylbenzyl groups directly bonded to a carbon atom, for example. The vinylbenzyl compound may contain an aromatic hydrocarbon structure, for example. The vinylbenzyl compound may be a compound which has two or more vinylbenzyl groups directly bonded to a carbon atom, and contains an aromatic hydrocarbon structure, for example.

It is preferable that the vinylbenzyl compound is a hydrocarbon compound. The vinylbenzyl compound may be a hydrocarbon compound having, in addition to vinylbenzyl groups, a non-aromatic hydrocarbon structure such as a chain hydrocarbon structure or an alicyclic hydrocarbon structure, or an aromatic hydrocarbon structure. It is preferable that the vinylbenzyl compound is a hydrocarbon compound having, in addition to vinylbenzyl groups, an aromatic hydrocarbon structure.

Examples of the aromatic hydrocarbon structure may include a monocyclic or polycyclic aromatic ring, a fused ring of two or more aromatic rings, a fused ring of an aromatic ring and a non-aromatic ring, and the like.

Examples of the aromatic hydrocarbon structure include an indene ring, an indane ring, a phenanthrene ring, an acenaphthylene ring, a fluorene ring, and the like. The indene ring, the indane ring, the phenanthrene ring, the acenaphthylene ring, the fluorene ring, and the like may be substituted or unsubstituted. From the viewpoint of dielectric properties, the indene ring or the fluorene ring is preferable.

More preferably, the vinylbenzyl compound is a compound having an indene ring. The vinylbenzyl compound may be a hydrocarbon compound having an indene ring, for example. It is preferable that a vinylbenzyl group is directly bonded to a carbon atom on a ring of an aromatic hydrocarbon structure.

The monomer as the vinylbenzyl compound will be described below.

The vinylbenzyl compound as the monomer may contain an aromatic hydrocarbon structure. It is preferable that the vinylbenzyl compound as the monomer is a hydrocarbon compound. The vinylbenzyl compound as the monomer may be a hydrocarbon compound containing an aromatic hydrocarbon structure, for example. As the aromatic hydrocarbon structure, an indene ring, an indane ring, a phenanthrene ring, an acenaphthylene ring, a fluorene ring, or a combination thereof is preferable, an indene ring, a fluorene ring, or a combination thereof is more preferable, and an indene ring is even more preferable, for example. The vinylbenzyl compound may be a monomer having one or two or more vinylbenzyl groups, and having one indene ring, in one molecule, for example. The vinylbenzyl compound may be a monomer as a hydrocarbon compound having one indene ring, and one or two or more vinylbenzyl groups in one molecule, for example.

One example of the vinylbenzyl compound is a monomer having an indene ring, and one or two or more vinylbenzyl groups bonded to any of the 1-position, 2-position, and 3-position of the indene ring. The vinylbenzyl compound may be a compound having an indene ring, one or two or more vinylbenzyl groups bonded to any of the 1-position, 2-position, and 3-position of the indene ring, and further a substituent other than the vinylbenzyl group, which is directly bonded to a carbon atom of the indene ring, for example. The vinylbenzyl compound may be a compound having an indene ring, and one or two or more vinylbenzyl groups bonded to any of the 1-position, 2-position, and 3-position of the indene ring, and not having a substituent other than the vinylbenzyl group, for example.

Specific examples of the vinylbenzyl compound include a monomer represented by general formula (1) below.

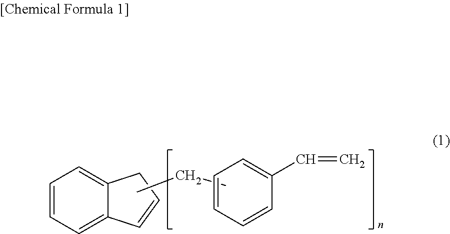

In general formula (1), n is 1, 2, or 3, but n may be 2 or 3. The mixture of monomers represented by general formula (1) may include a plurality of monomers having different n values. In this case, n is preferably in a range from 2 to 3 on average, and more preferably in a range from 2.0 to 2.5 on average.

In general formula (1), the vinylbenzyl group may be directly bonded to a carbon atom of any of the 1-position, 2-position, and 3-position of the indene ring. It is preferable that the vinylbenzyl group is bonded to the 1-position or a combination of the 1-position and 3-position. One or two vinylbenzyl groups may be bonded to each position. The vinylbenzyl group may be bonded to a combination of the 1-position, 1′-position, and 3-position of the indene ring, or to a combination of the 1-position and 1′-position of the indene ring, for example.

In general formula (1), a methylene group of the vinylbenzyl group may be at any position of o, m, and p, and a position of m or p is preferable. When a polymer is obtained by using two or more monomers, the polymer may be a mixture of an o-isomer, m-isomer, and p-isomer. In this case, a combination of the m-isomer and p-isomer is preferable, and the mass ratio between the m-isomer and the p-isomer is preferably in a range from 40:60 to 60:40.

A method for synthesizing the monomer as the vinylbenzyl compound will be described below. The vinylbenzyl compound is specified by a molecular structure thereof regardless of the following synthesis method.

An example of the method for synthesizing the monomer as the vinylbenzyl compound is a method of reacting a base compound having a desired structure such as indene or fluorine, with styrene having a methyl halide group, in the presence of a basic compound. Examples of the styrene having a methyl halide group include o-chloromethylstyrene, m-chloromethylstyrene, p-chloromethylstyrene, and the like. One of them may be used alone, or a mixture of two or more may be used. Examples of the basic compound include an alkali metal hydroxide, an alkali metal alkoxide, and the like.

A phase transfer catalyst may be used in the above reaction. Examples of the phase transfer catalyst include tetra-n-butylammonium bromide. The reaction may be performed by means of solution polymerization. The reaction may be performed with heating and stirring, for example. A polymerization inhibitor may be added to a reaction system. The obtained product may be purified by means of a known method such as concentration, reprecipitation, or cleaning, if necessary.

The obtained monomer may be a single compound or a monomer mixture of two or more compounds. When indene is used as the base compound, a compound is synthesized, in which a vinylbenzyl group is directly bonded to a carbon atom of at least one of the 1-position, 2-position, and 3-position of the indene ring, for example. The monomer mixture may contain vinylbenzyl compounds of two or more isomers with different bonding sites. Depending on synthetic conditions, it is possible to obtain a compound in which vinylbenzyl groups are directly bonded to carbon atoms of at least two of the 1-position, 2-position, and 3-position of the indene ring. In this case, the monomer mixture may contain two or more vinylbenzyl compounds with different bonding numbers and bonding sites of the vinylbenzyl groups to the indene ring.

When the vinylbenzyl compound is a monomer, the molecular weight is not particularly limited, but the molecular weight is preferably in a range from 200 to 800, more preferably in a range from 250 to 750, and even more preferably in a range from 300 to 700, from the viewpoint of achieving moldability and handleability. When the vinylbenzyl compound is a monomer, with respect to a mixture of a plurality of compounds, the molecular weight is regarded as a weight average molecular weight (Mw).

The prepolymer as the vinylbenzyl compound will be described below.

The vinylbenzyl compound as the prepolymer may contain an aromatic hydrocarbon structure. It is preferable that the vinylbenzyl compound as the prepolymer is a hydrocarbon compound. The vinylbenzyl compound as the prepolymer may be a hydrocarbon compound containing an aromatic hydrocarbon structure, for example. As the aromatic hydrocarbon structure, an indene ring, an indane ring, a phenanthrene ring, an acenaphthylene ring, a fluorene ring, or a combination thereof is preferable, an indene ring, a fluorene ring, or a combination thereof is more preferable, and an indene ring is even more preferable, for example. The vinylbenzyl compound may be a prepolymer having one or two or more vinylbenzyl groups and containing a structural unit with one indene ring, for example. The vinylbenzyl compound may be a prepolymer which is a hydrocarbon compound having one or two or more vinylbenzyl groups and containing a structural unit with one indene ring, for example.

The prepolymer can be obtained by polymerizing a monomer. It is preferable that a vinylbenzyl group derived from a monomer is introduced. A monomer with one or two or more vinylbenzyl groups may be used, and preferably a monomer with two or more vinylbenzyl groups may be used, for example. Polymerization is preferably stopped in a state where a certain amount of vinylbenzyl groups derived from monomers remain without fully completing the polymerization. In order to obtain a curable prepolymer in a liquid state, the polymerization may be stopped in a state where the viscosity of a polymerization reaction system of the curable prepolymer reaches a certain level. In the polymerization for obtaining the prepolymer, an oligomer may be used together with the monomer or instead of the monomer. In the polymerization for obtaining the prepolymer, the monomer of the vinylbenzyl compound described above may be used, or an oligomer of the monomer may be used, for example.

When the vinylbenzyl compound is a prepolymer, the weight average molecular weight (Mw) may be in a range from 5,000 to 50,000 or in a range from 10,000 to 30,000, from the viewpoint of the fluidity of the resin composition.

Next, a description will be given regarding a method for obtaining the vinylbenzyl compound as the prepolymer by polymerizing a vinylbenzyl compound. It is preferable that the vinylbenzyl compound is radically polymerized so as not to generate a polar component in the reaction product. The radical polymerization can be performed using a radical polymerization initiator. The polymerization can be performed by means of solution polymerization, and a polymerization solvent is not particularly limited. One or a combination of two or more organic solvents used in the resin composition described later may be used as the polymerization solvent, for example.

The radical polymerization initiator may be a thermal radical polymerization initiator or a photoradical polymerization initiator, but a thermal radical polymerization initiator is preferable. The radical polymerization initiator is not particularly limited, and examples thereof include an azo-based polymerization initiator, an organic peroxide-based polymerization initiator, and the like.

Examples of the azo-based polymerization initiator include 2,2′-azobis(isobutyronitrile), 2,2′-azobis(2-methylpropanenitrile), 2,2′-azobis(2-methylbutyronitrile), 2,2′-azobis(4-methoxy-2,4-dimethylvaleronitrile), 2,2′-azobis(2-methylpropionic acid)dimethyl, 1,1′-azobis(methylcyclohexylcarboxylate), 2,2′-azobis[N-(2-propenyl)-2-methylpropionamide], 2,2′-azobis(N-butyl-2-methylpropionamide), 4,4′-azobis(3,3,4,4,5,5,6,6,7,7,8,8,8-tridecafluorooctyl 4-cyanopentanoate), 1,1′-azobis(cyclohexane-1-carbonitrile), and the like.

Examples of the organic peroxide-based polymerization initiator include dicumyl peroxide, dibenzoyl peroxide, 2-butanone peroxide, tert-butyl perbenzoate, di-tert-butyl peroxide, 2,5-dimethyl-2,5-di(t-butyl peroxy)hexane, bis(tert-butyl peroxyisopropyl)benzene, tert-butyl hydroperoxide, and the like.

In order to prevent a polar component from being mixed with the resin composition, it is preferable to reduce the generation of a by-product exhibiting a polarity in a polymerization system. From this viewpoint, it is preferable to use a compound with a small amount of oxygen atoms, from among the radical polymerization initiators. As this kind of compound, an azo-based polymerization initiator is preferable. In particular, it is preferable that the azo-based polymerization initiator is a compound containing two nitrogen atoms (N) of an azo group, but not containing heteroatoms other than the nitrogen atoms. An example of the azo-based polymerization initiator is a compound represented by general formula (2) below.

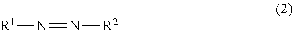

In general formula (2), R¹ and R² are each independently a hydrogen atom or a monovalent functional group, and at least one of R¹ and R² is a monovalent functional group. R¹ and R² may be the same, or different from each other. The monovalent functional group is preferably a hydrocarbon group, may be a saturated hydrocarbon group or an unsaturated hydrocarbon group, and may be an aliphatic hydrocarbon group or an aromatic hydrocarbon group. The monovalent functional group is preferably a saturated or unsaturated aliphatic hydrocarbon group, and preferably an alkyl group.

The alkyl group may be either a chain alkyl group or a cyclic alkyl group. The chain alkyl group may be a straight chain alkyl group or a branched alkyl group. The cyclic alkyl group may have a substituent which is bonded to a carbon atom on a ring.

The alkyl group may be an alkyl group of 1 to 10 carbon atoms, an alkyl group of 3 to 8 carbon atoms, or an alkyl group of 4 to 8 carbon atoms. Examples of the alkyl group include a methyl group, an ethyl group, an n-propyl group, an isopropyl group, an n-butyl group, an isobutyl group, a sec-butyl group, a tert-butyl group, an n-pentyl group, an isopentyl group, a neopentyl group, an n-hexyl group, an isohexyl group, a cyclohexyl group, a methylcyclohexyl group, a cyclohexylmethyl group, a heptyl group, an octyl group, an isooctyl group, a 2-ethylhexyl group, a nonyl group, a decyl group, a 1,1′,3,3′-tetramethylbutyl group, a 2,2′,4,4′-tetramethylbutyl group, and the like.

Specific examples of the compound represented by general formula (2) include 2,2′-azobis(2,4,4-trimethylpentane), 2,2′-azobis(2,4-dimethylvaleronitrile), and the like.

One radical polymerization initiator may be used alone, or a combination of two or more may be used.

The amount used of the radical polymerization initiator may be appropriately selected according to the degree of polymerization of a desired prepolymer. The amount used of the radical polymerization initiator may be in a range from 0.05 parts by mass to 5 parts by mass, in a range from 0.1 parts by mass to 4 parts by mass, or in a range from 0.5 parts by mass to 2 parts by mass, relative to 100 parts by mass of the vinylbenzyl compound in the polymerization system, for example.

The vinylbenzyl compound as the prepolymer may be a homopolymer or a copolymer of the vinylbenzyl compound. The copolymer may be a copolymer of two or more vinylbenzyl compounds, or a copolymer of a vinylbenzyl compound and another monomer. When the vinylbenzyl compound is a copolymer, the vinylbenzyl compound may be a random copolymer, a block copolymer, or the like.

The oligomer as the vinylbenzyl compound may be a polymer having a low degree of polymerization of the monomer described above.

From the viewpoint of moldability, the amount of the (A) component may be 10% by mass or more, 20% by mass or more, or 30% by mass or more, relative to the solid fraction amount of the resin composition. Meanwhile, from the viewpoint of flame retardancy, the amount of the (A) component may be 70% by mass or less, 60% by mass or less, 50% by mass or less, 40% by mass or less, or 30% by mass or less, relative to the solid fraction amount of the resin composition. The amount of the (A) component may be in a range from 10% by mass to 70% by mass, in a range from 10% by mass to 60% by mass, in a range from 20% by mass to 50% by mass, in a range from 30% by mass to 40% by mass, in a range from 10% by mass to 20% by mass, in a range from 20% by mass to 30% by mass, or in a range from 30% by mass to 40% by mass, relative to the solid fraction amount of the resin composition, for example.

In the present disclosure, “solid fraction” of the resin composition refers to a component in the resin composition other than a volatile substance such as water or a solvent described later. The solid fraction is a component which remains without being volatilized when the resin composition is dried. The solid fraction also includes a liquid, starch syrup, or wax-like component at room temperature of about 25° C., and does not necessarily have to be a solid component.

From the viewpoint of moldability, the amount of the (A) component may be 50% by mass or more, 60% by mass or more, or 70% by mass or more, relative to the total amount of the (A) component and the (B) component described later (the (B) acenaphthylene polymer with a number average molecular weight of 1,000 or more). Meanwhile, from the viewpoint of flame retardancy, the amount of the (A) component may be 99% by mass or less, 95% by mass or less, or 90% by mass or less, relative to the total amount of the (A) component and the (B) component. The amount of the (A) component may be in a range from 50% by mass to 99% by mass, in a range from 60% by mass to 95% by mass, or in a range from 70% by mass to 90% by mass, relative to the total amount of the (A) component and the (B) component, for example.

<(B) Acenaphthylene Polymer with a Number Average Molecular Weight of 1,000 or More>

The (B) acenaphthylene polymer may have a structural unit derived from acenaphthylene. The structural unit derived from acenaphthylene may be substituted or unsubstituted.

It is preferable that the (B) acenaphthylene polymer has a structural unit with an acenaphthene structure represented by formula (3) below. In formula (3) below, a symbol * represents a bonding position with another structural unit. In formula (3) below, the acenaphthene structure may not have a substituent or may have one or more substituents. Examples of the substituent include an alkyl group. The alkyl group may be either a chain alkyl group or a cyclic alkyl group. The alkyl group may be an alkyl group of 1 to 10 carbon atoms, or an alkyl group of 1 to 4 carbon atoms, for example. Examples of the alkyl group include a methyl group, an ethyl group, a propyl group, a butyl group, and the like.

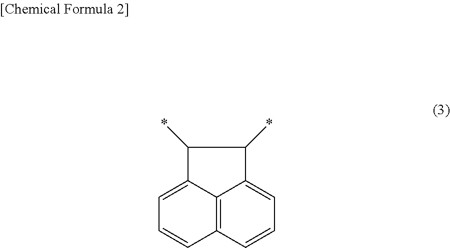 [SMILES: *C1c2cccc3cccc(c23)C1*]

The (B) acenaphthylene polymer may be a homopolymer or a copolymer of acenaphthylene. The copolymer may be a copolymer of two or more monomers selected from the group consisting of substituted or unsubstituted acenaphthylene, or a copolymer of acenaphthylene and another monomer. When the acenaphthylene polymer is a copolymer, the acenaphthylene polymer may be a random copolymer, a block copolymer, or the like.

The (B) acenaphthylene polymer may have 50% by mass or more, 70% by mass or more, 90% by mass or more, or 95% by mass or more, of structural units derived from acenaphthylene, for example. The (B) acenaphthylene polymer may have 50% by mass or more, 70% by mass or more, 90% by mass or more, or 950% by mass or more, of structural units represented by formula (3), for example.

It is preferable that the (B) acenaphthylene polymer is a homopolymer of acenaphthylene. The (B) acenaphthylene polymer may be a homopolymer of unsubstituted acenaphthylene, for example.

The number average molecular weight (Mn) of the (B) acenaphthylene polymer is preferably 1,000 or more, from the viewpoint of easily obtaining low sublimability.

The number average molecular weight (Mn) of the (B) acenaphthylene polymer is preferably 2,000 or more, more preferably 5,000 or more, and even more preferably 20,000 or more. The number average molecular weight (Mn) of the (B) acenaphthylene polymer may be 100,000 or less, or 50,000 or less. The number average molecular weight (Mn) of the (B) acenaphthylene polymer may be in a range from 1,000 to 100,000, in a range from 2,000 to 100,000, in a range from 5,000 to 50,0000, or in a range from 20,00 to 50,000, for example.

The weight average molecular weight (Mw) of the (B) acenaphthylene polymer is preferably 2,000 or more, more preferably 5,000 or more, and even more preferably 10,000 or more. The weight average molecular weight (Mw) of the (B) acenaphthylene polymer may be 1,000,000 or less, or 500,000 or less. The weight average molecular weight (Mw) of the (B) acenaphthylene polymer may be in a range from 2,000 to 1,000,000, in a range from 5,000 to 1,000,000, or in a range from 10,000 to 500,000, for example.

The (B) acenaphthylene polymer can be obtained by polymerizing acenaphthylene and, if necessary, another monomer or the like, for example. The polymerization may be performed by means of radical polymerization, for example. The radical polymerization can be performed using a radical polymerization initiator. The polymerization can be performed by means of solution polymerization, and a polymerization solvent is not particularly limited. One or a combination of two or more of organic solvents used in the resin composition described later may be used as the polymerization solvent, for example.

The radical polymerization initiator is not particularly limited, and examples thereof include an azo-based polymerization initiator, an organic peroxide-based polymerization initiator, and the like. Specifically, the initiator may be appropriately selected and used from an azo-based polymerization initiator, an organic peroxide-based polymerization initiator, and the like as exemplified in the description of the method for obtaining the vinylbenzyl compound as the prepolymer.

When radical polymerization is used, the (B) acenaphthylene polymer can be obtained by heating a polymerization solution in a nitrogen atmosphere, the polymerization solution being obtained by adding a radical polymerization initiator and a polymerization solvent to an acenaphthylene monomer and, if necessary, another monomer. The amount of the radical polymerization initiator may be in a range from 0.1 parts by mass to 10 parts by mass, and may be about 5 parts by mass, relative to 100 parts by mass of the monomer, for example. The amount of the polymerization solvent may be the amount in which the total amount of the monomer and the polymerization initiator in the polymerization solution is in a range from 5% by mass to 80% by mass, for example. Further, the amount of the polymerization solvent may be the amount in which the total amount of the monomer and the polymerization initiator in the polymerization solution is about 30% by mass. The heating temperature may be in a range from 50° C. to 150° C., and may be about 110° C., for example. The heating time may be in a range from 1 hour to 50 hours, and may be about 15 hours, for example.

One (B) acenaphthylene polymer may be used alone, or a combination of two or more may be used.

From the viewpoint of flame retardancy, the amount of the (B) component may be 0.10% by mass or more, 1% by mass or more, or 5% by mass or more, relative to the solid fraction amount of the resin composition. Meanwhile, the amount of the (B) component may be 40% by mass or less, 30% by mass or less, 20% by mass or less, or 10% by mass or less, relative to the solid fraction amount of the resin composition. The amount of the (B) component may be in a range from 0.10% by mass to 40% by mass, in a range from 1% by mass to 30% by mass, in a range from 1% by mass to 20% by mass, or in a range from 5% by mass to 10% by mass, relative to the solid fraction amount of the resin composition, for example.

From the viewpoint of flame retardancy, the amount of the (B) component may be 1% by mass or more, 5% by mass or more, or 10% by mass or more, relative to the total amount of the (A) component and the (B) component. Meanwhile, from the viewpoint of moldability, the amount of the (B) component may be 50% by mass or less, 40% by mass or less, or 30% by mass or less, relative to the total amount of the (A) component and the (B) component. The amount of the (B) component may be in a range from 1% by mass to 50% by mass, in a range from 5% by mass to 40% by mass, or in a range from 10% by mass to 30% by mass, relative to the total amount of the (A) component and the (B) component, for example.

### <Other Components>

The resin composition may contain components other than each component described above, as necessary.

Examples of other components include a flame retardant, an inorganic filler, a solvent, a polymerization initiator, an elastomer, a resin other than each component described above, an antioxidant, a thermal stabilizer, an antistatic agent, an ultraviolet light absorber, a pigment, a colorant, a lubricant, and the like.

The resin composition may contain a flame retardant. Although there are no particular limitations on the flame retardant, a phosphorus-based flame retardant can be used as the flame retardant, for example.

Examples of the phosphorus-based flame retardant include aromatic phosphate ester compounds such as triphenylphosphate, tricresylphosphate, trixylenylphosphate, cresyldiphenylphosphate, cresyldi-2,6-xylenylphosphate, resorcinol bis(diphenylphosphate), 1,3-phenylenebis(di-2,6-xylenylphosphate), bisphenol A-bis(diphenylphosphate), and 1,3-phenylenebis(diphenylphosphate); phosphonate esters such as divinyl phenylphosphonate, diallyl phenylphosphonate, and bis(1-butenyl)phenylphosphonate; phosphinate esters such as phenyl diphenylphosphinate and methyl diphenylphosphinate; phosphazene compounds such as bis(2-allylphenoxy)phosphazene and dicresylphosphazene; 9,10-dihydro-9-oxa-10-phosphaphenanthrene-10-oxide, and a derivative thereof which is 10-(2,5-dihydroxyphenyl)-9,10-dihydro-9-oxa-10-phosphaphenanthrene-10-oxide; melamine phosphate, melamine pyrophosphate, melamine polyphosphate, melam polyphosphate, ammonium polyphosphate, phosphorus-containing vinylbenzyl compounds, metal salts of phosphinic acid compounds, red phosphorus, and the like.

One flame retardant may be used alone, or a combination of two or more may be used. The amount of the flame retardant may be in a range from 0.10% by mass to 30% by mass, in a range from 1% by mass to 20% by mass, in a range from 1% by mass to 10% by mass, in a range from 10% by mass to 20% by mass, or in a range from 20% by mass to 30% by mass, relative to the solid fraction amount of the resin composition, for example.

The resin composition may contain an inorganic filler. Examples of the inorganic filler include silica (SiO₂), alumina (Al₂O₃), titanium oxide, barium titanate, strontium titanate, potassium titanate, calcium titanate, aluminum carbonate, magnesium hydroxide, aluminum hydroxide, aluminum silicate, calcium carbonate, calcium silicate, magnesium silicate, silicon nitride, boron nitride, aluminum borate, silicon carbide, mica, beryllia, clay, talc, and the like. From the viewpoint of dielectric properties, it is preferable that the inorganic filler is silica.

The shape and size of the inorganic filler are not particularly limited. The average particle size of the inorganic filler may be in a range from 0.01 μm to 20 μm, or in a range from 0.1 μm to 10 μm, for example. The average particle size of the inorganic filler is the particle size of a point corresponding to an integrated value of 50% in a volume-based particle size distribution measured by means of a laser diffraction/scattering method.

One inorganic filler may be used alone, or a combination of two or more may be used.

The amount of the inorganic filler may be in a range from 10% by volume to 80% by volume, in a range from 20% by volume to 70% by volume, or in a range from 30% by volume to 60% by volume, relative to the solid fraction amount of the resin composition, for example.

The amount of the inorganic filler may be in a range from 30% by mass to 90% by mass, in a range from 40% by mass to 90% by mass, or in a range from 50% by mass to 80% by mass, relative to the solid fraction amount of the resin composition, for example.

The resin composition may further contain a polymerization initiator to promote curing of the (A) thermosetting resin.

A radical polymerization initiator can be used as the polymerization initiator. The radical polymerization initiator may be a thermal radical polymerization initiator or a photoradical polymerization initiator, but a thermal radical polymerization initiator is preferable. There are no particular limitations on the radical polymerization initiator, and examples thereof include an azo-based polymerization initiator, an organic peroxide-based polymerization initiator, and the like. Specifically, the polymerization initiator may be appropriately selected from an azo-based polymerization initiator, an organic peroxide-based polymerization initiator, and the like exemplified in the description of the method for obtaining the vinylbenzyl compound as the prepolymer.

One polymerization initiator may be used alone, or a combination of two or more may be used.

The amount used of the polymerization initiator may be appropriately adjusted, but may be in a rage from 0.01 parts by mass to 5 parts by mass, in a range from 0.1 parts by mass to 4 parts by mass, or in a range from 0.5 parts by mass to 2 parts by mass, relative to 100 parts by mass of the (A) thermosetting resin, for example.

Examples of the elastomer include a styrene-based elastomer, an olefin-based elastomer, a urethane-based elastomer, a polyester-based elastomer, a polyamide-based elastomer, an acrylic-based elastomer, a silicone-based elastomer, and the like. One elastomer may be used alone, or a combination of two or more may be used.

The resin composition may or may not contain a solvent. The resin composition may be a resin composition containing a liquid compound as the thermosetting resin but not containing a solvent, or may be a resin composition containing both a thermosetting resin and a solvent, for example. The solvent can further enhance coating properties by adjusting the viscosity of the resin composition. The solvent is preferably an organic solvent.

Examples of the organic solvent include alcohol-based solvents such as ethanol, propanol, butanol, methyl cellosolve, ethylene glycol monobutyl ether, and propylene glycol monomethyl ether; ketone-based solvents such as acetone, methylethylketone, methyl isobutyl ketone, and cyclohexanone; an ether-based solvent such as tetrahydrofuran; aromatic hydrocarbon-based solvents such as toluene, xylene, and mesitylene; nitrogen atom-containing solvents such as dimethylformamide, dimethylacetamide, and N-methylpyrrolidone; a sulfur atom-containing solvent such as dimethylsulfoxide, and an ester-based solvent such as y-butyrolactone. One organic solvent may be used alone, or a combination of two or more may be used.

When the resin composition contains a solvent, the solid fraction amount of the resin composition may be in a range from 10% by mass to 90% by mass, in a range from 30% by mass to 80% by mass, or in a range from 40% by mass to 75% by mass, relative to the total mass of the resin composition, for example.

### <Method for Producing Resin Composition>

A method for producing the resin composition is not particularly limited. The resin composition according to one embodiment is not limited by the method for producing the resin composition, and characteristics thereof are as described in the present disclosure. As an example of the method for producing the resin composition, the resin composition can be obtained by mixing the (A) thermosetting resin and the (B) acenaphthylene, and, if necessary, an added optional component. More specifically, the (A) thermosetting resin and the (B) acenaphthylene polymer are dissolved or dispersed in a solvent, and, if necessary, a flame retardant, an inorganic filler, and/or the like are added thereto, and they are mixed to obtain the resin composition. Conditions such as the mixing order of each component, temperature, and time are not particularly limited, and conditions may be appropriately adjusted in accordance with the type of raw materials, the scale of production, a production apparatus, and the like.

### <Dielectric Properties of Cured Product>

The dielectric constant (Dk) of a cured product of the resin composition at 25° C. and 10 GHz is preferably 4.0 or less, more preferably 3.5 or less, and even more preferably 3.4 or less. The smaller the dielectric constant (Dk) of the cured product of the resin composition at 25° C. and 10 GHz, the better, and there are no particular limitations on a lower limit thereof. However, the dielectric constant (Dk) may be 2.3 or more, or 2.4 or more, in consideration of the balance with other physical properties, for example.

The dielectric constant (Dk) of the cured product of the resin composition at 25° C. and 10 GHz may be in a range from 2.3 to 4.0, and is preferably in a range from 2.3 to 3.5, or in a range from 2.4 to 3.4, for example.

The dielectric loss tangent (Df) of the cured product of the resin composition at 25° C. and 10 GHz is preferably 0.0020 or less, more preferably 0.0015 or less, and even more preferably 0.0013 or less. The smaller the dielectric loss tangent (Df) of the cured product of the resin composition at 25° C. and 10 GHz, the better, and there are no particular limitations on a lower limit thereof. However, the dielectric loss tangent (Df) may be 0.0001 or more or 0.00050 or more in consideration of balance with other physical properties, for example.

The dielectric loss tangent (Df) of the cured product of the resin composition at 25° C. and 10 GHz may be in a range from 0.0001 to 0.0020, and is preferably in a range from 0.00050 to 0.0015, or in a range from 0.00050 to 0.0013, for example.

In the present disclosure, the dielectric constant (Dk) and the dielectric loss tangent (Df) at 25° C. and 10 GHz are measured at 25° C. in 10 GHz bands in accordance with an SPDR method (split post dielectric resonator). For a measuring device, it is possible to use “PNA Network Analyzer N5227A” (product name) by Agilent Technologies, Inc.

A sample, of which the dielectric constant (Dk) and the dielectric loss tangent (Df) of the cured product of the resin composition are to be measured, is obtained by curing the resin composition to be in a C-stage state according to JIS K 6800 (1985).

### [Prepreg]

According to one embodiment, it is possible to provide a prepreg formed using a resin composition. The prepreg can be formed using a resin composition and a fiber base material, for example. The resin composition described above can be used as the resin composition. The details of the resin composition are as described above.

The prepreg can contain the resin composition described above, or a semi-cured product of the resin composition described above.

In the present disclosure, an example of an index of the semi-cured product is a B-stage state in JIS K 6800 (1985).

The prepreg may contain the resin composition or the semi-cured product of the resin composition, and further a fiber base material such as a sheet-like fiber base material, for example. In the prepreg, the resin composition may be uncured, or the resin composition may be partially or entirely semi-cured. A molded article such as a laminated body is assembled using the prepreg and the article is cured by performing a heat treatment or the like thereto to obtain a cured product, for example.

The prepreg can be obtained by coating a resin composition on a fiber base material and drying, for example. The prepreg can be obtained by impregnating-coating a resin composition on a fiber base material and drying the fiber base material impregnated with the resin composition, for example. The drying is preferably performed at or above a temperature at which volatile components such as solvents that may be contained in the resin composition are removed. The drying may be performed at or above a temperature at which a thermosetting resin contained in the resin composition is semi-cured, depending on the application. The drying is preferably controlled such that a thermosetting resin contained in the resin composition is not completely cured. From this viewpoint, the drying temperature may be in a range from 80° C. to 200° C., for example. The drying time may be in a range from 1 minute to 30 minutes depending on the drying temperature, a drying apparatus, and a scale thereof, for example. The (B) acenaphthylene polymer has low sublimability, and therefore when the above-described resin composition containing the (B) acenaphthylene polymer is used, there is a tendency that contamination is unlikely to occur in a furnace.

The fiber base material may be any of a woven fabric, a knitted fabric, and a nonwoven fabric. The fiber base material may be provided in the form of a chopped strand mat, a roving, or the like.

A fiber material may be either an inorganic fiber or an organic fiber.

Examples of the inorganic fiber include a glass fiber, a carbon fiber, and the like. Examples of the glass fiber include E-glass, NE-glass, D-glass, S-glass, Q-glass, and the like. Examples of the organic fiber include polyimide, polyester, tetrafluoroethylene, and the like. The fiber base material may be a base material using one type of these fibers alone or a base material using a combination of two or more types of these fibers.

The material of the fiber base material is preferably an inorganic fiber and more preferably a glass fiber, from the viewpoint of dielectric properties and heat resistance.

The fiber base material may be appropriately selected depending on the use application of the prepreg, and preferably a sheet-like fiber base material.

The sheet-like fiber base material may be one of various sheet-like fiber base materials used in known laminates for electrically insulating materials.

The thickness of the sheet-like fiber base material is not particularly limited, but is preferably in a range from 0.02 mm to 0.5 mm, for example. The thicknesses at five points at equal distances on an entire surface of the sheet-like fiber base material are measured, and an arithmetic mean value of the five points refers to the thickness above.

### [Resin Film]

According to one embodiment, it is possible to provide a resin film formed using the resin composition. The resin film can be produced using the resin composition. The details of the resin composition are as described above.

The resin film may contain the resin composition described above, or a semi-cured product of the resin composition described above. In the resin film, the resin composition may be uncured, or the resin composition may be partially or entirely semi-cured. A cured product can be obtained by performing a heat treatment or the like to the resin film to cure the film, for example.

The resin film can be obtained by coating a resin composition on a material to be coated and drying, for example. The drying may be performed in the same manner as the method for producing the prepreg, for example. After the resin film is dried on the material to be coated, a product may be provided as a combination of the resin film and the material to be coated. In this method, it is possible to provide a resin film for forming an insulating layer or the like on a material to be coated in an electronic device or the like, for example. In another method, after a resin film is dried on a material to be coated, the resin film is peeled off from the material to be coated to provide the resin film as a product.

The material to be coated may be either an inorganic base material or an organic base material. Examples of the material to be coated include a glass base material, a metal base material such as a metal foil or a metal plate, a plastic base material such as a plastic plate or a plastic film, a paper base material, and the like. The material to be coated may be the fiber base material described for the prepreg above. In order to peel off the resin film from the material to be coated and provide the resin film as a product, it is possible to use a material to be coated having a release layer formed on a surface thereof.

### [Metal-Clad Laminate]

According to one embodiment, it is possible to provide a metal-clad laminate containing a cured product of a resin composition, and a metal foil. The metal-clad laminate may contain a cured product of a prepreg and a metal foil, for example.

According to another embodiment, it is possible to provide a metal-clad laminate formed using a prepreg and a metal foil. This metal-clad laminate may contain a cured product of a prepreg and a metal foil, for example.

The details of the resin composition and the prepreg are as described above.

It is preferable that a metal-clad laminate has a cured resin layer containing a cured resin product and a metal foil disposed on at least one surface of the cured resin layer. The cured resin layer contains the cured product of the resin composition described above, but may contain the cured product of the prepreg described above. In the metal-clad laminate, a metal foil is disposed on at least one surface of the cured product of the prepreg, and more preferably, metal foils are disposed on both surfaces of the cured product of the prepreg, for example. The metal-clad laminate may be produced by disposing a metal foil on at least one surface of one sheet-like prepreg. Alternatively, the metal-clad laminate may be produced by disposing a metal foil on at least one outermost surface of a laminated body obtained by laminating two or more sheet-like prepregs. The metal-clad laminate may be produced by disposing metal foils on both surfaces of a laminated body obtained by laminating two or more sheet-like prepregs, for example.

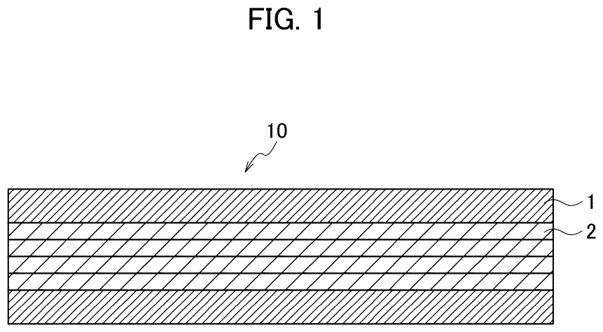

As a specific example of a method for producing a metal-clad laminate, a method of disposing a metal foil on a laminated body of two or more sheet-like prepregs will be described below. As a specific example of a metal-clad laminate, FIG. 1 is a schematic cross-sectional view illustrating a metal-clad laminate 10 containing a plurality of cured products 2 of prepregs and a metal foil 1.

First, two or more sheet-like prepregs are laminated to obtain a laminated body. The two or more sheet-like prepregs in the laminated body may be identical to each other, or partially or entirely different from each other. It is sufficient if at least one of the two or more sheet-like prepregs in the laminated body is obtained using the resin composition according to an embodiment.

Next, a metal foil is disposed on at least one surface of the laminated body.

The laminated body on which the metal foil is disposed is heated, and pressure is applied thereto. This promotes a curing reaction of the sheet-like prepregs, and accordingly it is possible to obtain cured products of the prepregs. Further, sheet-like prepregs adjacent to each other can be fixed. Heating and pressure conditions are not particularly limited, but a temperature may be in a range from 100° C. to 300° C., a time may be in a range from 10 minutes to 300 minutes, and a pressure may be in a range from 1.5 MPa to 5 MPa, for example. After heating and applying pressure to the laminated body, the laminated body may be reheated in order to further proceed the curing of the prepregs. In this case, a reheating temperature may be in a range from 100° C. to 300° C.

For performing pressure application, it is possible to use an autoclave molding machine, a multistage press, a multistage vacuum press, a continuous molding machine, or the like, for example.

The (B) acenaphthylene polymer has low sublimability, and therefore when the above-described resin composition containing the (B) acenaphthylene polymer is used, there is a tendency that contamination is unlikely to occur in a furnace.

A metal of the metal foil is not particularly limited, and examples thereof include copper, nickel, aluminum, gold, silver, platinum, molybdenum, ruthenium, tungsten, iron, titanium, chromium, and an alloy containing two or more metal elements from thereamong. Industrially, it is preferable that the metal is a simple metal such as copper, nickel, or aluminum. If copper is used as the metal foil, it is possible to provide a copper-clad laminate.

The dielectric properties of the assembled metal-clad laminate from which the metal foil is removed are preferably as follows. A state in which the metal foil is removed from the metal-clad laminate is also simply referred to as a metal foil removed material.

The dielectric constant (Dk) of the metal foil removed material at 25° C. and 10 GHz is preferably 4.0 or less, more preferably 3.5 or less, and even more preferably 3.4 or less. The smaller the dielectric constant (Dk) of the metal foil removed material at 25° C. and 10 GHz, the better, and there are no particular limitations on a lower limit thereof. However, the dielectric constant (Dk) may be 2.3 or more, or 2.4 or more, in consideration of the balance with other physical properties, for example.

The dielectric constant (Dk) of the metal foil removed material at 25° C. and 10 GHz may be in a range from 2.3 to 4.0, and is preferably in a range from 2.3 to 3.5, or in a range from 2.4 to 3.4, for example.

The dielectric loss tangent (Df) of the metal foil removed material at 25° C. and 10 GHz is preferably 0.0020 or less, more preferably 0.0015 or less, and even more preferably 0.0013 or less. The smaller the dielectric loss tangent (Df) of the metal foil removed material at 25° C. and 10 GHz, the better, and there are no particular limitations on a lower limit thereof. However, the dielectric loss tangent (Df) may be 0.0001 or more or 0.00050 or more in consideration ofthe balance with other physical properties, for example.

The dielectric loss tangent (Df) of the metal foil removed material at 25° C. and 10 GHz may be in a range from 0.0001 to 0.0020, and is preferably in a range from 0.00050 to 0.0015, or in a range from 0.00050 to 0.0013, for example.

The measurement of the dielectric constant (Dk) and the dielectric loss tangent (Df) of the metal foil removed material may be performed according to the measurement of the dielectric constant (Dk) and the dielectric loss tangent (Df) of the cured product of the resin composition described above.

A sample used for the measurement of the dielectric constant (Dk) and the dielectric loss tangent (Df) of the metal foil removed material is obtained by immersing the metal-clad laminate in an etching solution to remove the metal foil, and then cutting out an evaluation substrate of 60 mm and 100 mm from the test piece from which the metal foil has been removed. In the case of a copper-clad laminate, an ammonium persulfate solution (10% by mass) is used as the etching solution.

### [Printed Wiring Board]

According to one embodiment, it is possible to provide a printed wiring board containing a cured product of a resin composition. The details of the resin composition are as described above.

The cured product of the resin composition in the printed wiring board can be produced using a resin composition, a prepreg, a resin film, a metal-clad laminate, or a combination thereof. It is possible to provide a printed wiring board by forming wiring on a cured product of a prepreg by means of a known method, for example. In another example, it is possible to provide a printed wiring board by forming wiring using a metal-clad laminate by means of a known method. The printed wiring board may be a combination of these examples. The details of the prepreg, the resin film, and the metal-clad laminate are as described above.

The printed wiring board may be either a single-layer printed wiring board or a multi-layer printed wiring board.

### [Semiconductor Package]

According to one embodiment, it is possible to provide a semiconductor package having a printed wiring board and a semiconductor element. More specifically, it is possible to provide a semiconductor package having a semiconductor element, and a printed wiring board containing a cured product of a resin composition. The details of the resin composition are as described above. The details of the cured product of the resin composition, and the printed wiring board are also as described above. The semiconductor package can be produced by mounting a semiconductor element, a memory, or the like on a printed wiring board by means of a known method, for example. The cured product of the resin composition may be used as an insulating material, a sealing material, or the like of the semiconductor package.

[Acenaphthylene Homopolymer with a Number Average Molecular Weight of 1,000 or More]

According to one embodiment, it is possible to provide an acenaphthylene homopolymer with a number average molecular weight of 1,000 or more (hereinafter, the term “acenaphthylene homopolymer” may be simply used). The acenaphthylene homopolymer can have a structural unit derived from acenaphthylene. The structural unit derived from acenaphthylene can be substituted or unsubstituted.

The acenaphthylene homopolymer is a homopolymer of acenaphthylene, and more specifically, is a homopolymer of substituted or unsubstituted acenaphthylene. The acenaphthylene homopolymer may be a homopolymer of unsubstituted acenaphthylene, for example.

The acenaphthylene homopolymer can have a structure with a structural unit having an acenaphthene structure represented by formula (4) below. In formula (4), n represents an integer in a range for which the number average molecular weight is 1,000 or more.

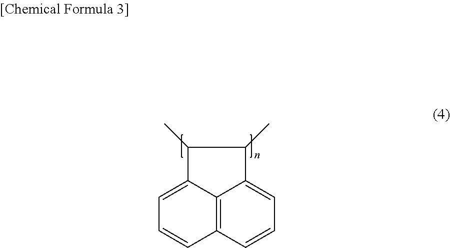

In formula (4), the acenaphthene structure may have no substituent, or may have one or more substituents. Examples of the substituent include an alkyl group. The alkyl group may be either a chain alkyl group or a cyclic alkyl group. The alkyl group may be an alkyl group of 1 to 10 carbon atoms, or an alkyl group of 1 to 4 carbon atoms, for example. Examples of the alkyl group include a methyl group, an ethyl group, a propyl group, a butyl group, and the like.

From the viewpoint of easily obtaining low sublimability, the number average molecular weight (Mn) of the acenaphthylene homopolymer is preferably 1,000 or more.

The number average molecular weight (Mn) of the acenaphthylene homopolymer is more preferably 2,000 or more, and even more preferably 5,000 or more. The number average molecular weight (Mn) of the acenaphthylene homopolymer may be 100,000 or less, or 50,000 or less. The number average molecular weight (Mn) of the acenaphthylene homopolymer may be in a range from 1,000 to 100,000, in a range from 2,000 to 100,000, or in a range from 5,000 to 50,0000, for example.

The weight average molecular weight (Mw) of the acenaphthylene homopolymer is preferably 2,000 or more, more preferably 5,000 or more, and even more preferably 10,000 or more. The weight average molecular weight (Mw) of the acenaphthylene homopolymer may be 1,000,000 or less, or 500,000 or less. The weight average molecular weight (Mw) of the acenaphthylene homopolymer may be in a range from 2,000 to 1,000,000, in a range from 5,000 to 1,000,000, or in a range from 10,000 to 500,000, for example.

An example of a method for producing the acenaphthylene homopolymer is a method of performing homopolymerization using acenaphthylene as a monomer in the method described above as the method for producing the (B) acenaphthylene polymer.

Preferred examples of the embodiments of the present disclosure will be described below. The embodiments of the present invention are not limited to the following examples.

<1>

A resin composition including: an (A) thermosetting resin; and a (B) acenaphthylene polymer with a number average molecular weight of 1,000 or more.

<2>

The resin composition according to <1>, in which an amount of the (B) acenaphthylene polymer with a number average molecular weight of 1,000 or more is 5% by mass or more, relative to a total amount of the (A) thermosetting resin and the (B) acenaphthylene polymer with a number average molecular weight of 1,000 or more.

<3>

The resin composition according to <1> or <2>, in which the (A) thermosetting resin includes a compound with a vinylbenzyl group.

<4>

A prepreg formed using the resin composition according to any one of <1> to <3>.

<5>

A resin film formed using the resin composition according to any one of <1> to <3>.

<6>

A metal-clad laminate including: a metal foil, and a cured product of the resin composition according to any one of <1> to <3>.

<7>

A metal-clad laminate formed using the prepreg according to <4> and a metal foil.

<8>

A printed wiring board including: a cured product of the resin composition according to any one of <1> to <3>.

<9>

A semiconductor package including: the printed wiring board according to <8>, and a semiconductor element.

<10>

An acenaphthylene homopolymer having a number average molecular weight of 1,000 or more.

The disclosure of the present application is related to the subject matter described in Japanese Patent Application No. 2023-063536 filed on Apr. 10, 2023, the entire disclosed contents of which are incorporated herein by reference.

### EXAMPLES

Hereinafter, the present embodiment will be described more specifically by way of examples, but the present embodiment is not limited to the examples below.

### [Production of Vinylbenzyl Compound]

The following were added to a reaction container with a volume of 500 mL, equipped with a stirrer, a thermometer, a reflux tube, and a nitrogen blowing port: 35.6 parts by mass of indene, 101.2 parts by mass of following chloromethylstyrene, 7.1 parts by mass of tetra-n-butylammonium bromide (manufactured by KANTO CHEMICAL CO., INC.) as a phase transfer catalyst, 0.1 parts by mass of phenothiazine as a polymerization inhibitor, and 77.6 parts by mass of toluene as a solvent. The mixture was heated and stirred at 40° C., while blowing nitrogen thereto at a flow rate of 50 mL/minute.

Chloromethylstyrene “CMS-P”: AGC Seimi Chemical Co., Ltd., a mixture of m-isomer and p-isomer, the m-isomer amount is 50% by mass, and the p-isomer amount is 50% by mass

Next, 46.5 parts by mass of an aqueous solution of a basic compound below was added dropwise for 20 minutes, and the mixture was further stirred at 60° C. for nine hours. Blowing of nitrogen was continued during the reaction. The mixture was cooled to room temperature (25° C.), and neutralized with a hydrochloric acid 10% in aqueous solution. Thereafter, the mixture was washed twice with pure water, and toluene was removed by distillation under reduced pressure. Thereafter, a viscous liquid obtained was washed with methanol and then dried in vacuum to obtain a vinylbenzyl compound.

Aqueous solution of basic compound: an aqueous solution of sodium hydroxide with a concentration of 48% by mass, KANTO CHEMICAL CO., INC.

By means of ¹H-NMR analysis, it was confirmed that the obtained vinylbenzyl compound had a structure with a vinylbenzyl group directly bonded to a carbon atom in the 1-position, 3-position, or a combination thereof, of indene represented by formula (5) below. In addition, by means of GPC analysis, it was confirmed that the vinylbenzyl compound was a mixture of a compound in which two vinylbenzyl groups were introduced, and a compound in which three vinylbenzyl groups were introduced. It was confirmed that when three vinylbenzyl groups were introduced into the vinylbenzyl compound, the compound had two vinylbenzyl groups directly bonded to carbon atoms of the 1-position of the indene ring, and one vinylbenzyl group directly bonded to a carbon atom of the 3-position. The weight average molecular weight (Mw) of the vinylbenzyl compound was 500. The weight average molecular weight was measured by means of the following method.

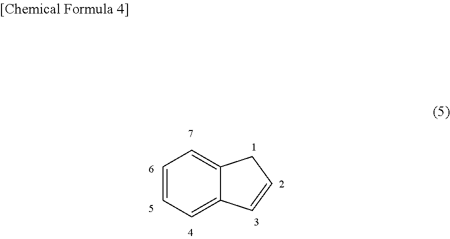

### [Method for Measuring Weight Average Molecular Weight (Mw)]

The weight average molecular weight was obtained through measurement by gel permeation chromatography (GPC), and conversion with the use of a calibration curve of standard polystyrene. The calibration curve was approximated by a cubic equation using standard polystyrene: TSKstandard POLYSTYRENE (Type; A-2500, A-5000, F-20, and F-80) (manufactured by Tosoh Corporation, product name). The measurement conditions of GPC are as follows.

System: High Performance GPC System HLC-8320GPC (Tosoh Corporation, product name)

Detector: UV Detector UV-8320 (Tosoh Corporation, product name)

Column: guard column; TSKgel guardcolumn Super (HZ)-M+, column; TSKgel SuperMultipore HZ-M (two columns), reference column; TSKgel SuperH-RC (two columns) (all manufactured by Tosoh Corporation, product names)

Column sizes: 4.6 mm×20 mm (guard column), 4.6 mm×150 mm (column), 6.0 mm×150 mm (reference column)

Eluent: tetrahydrofuran

Sample concentration: 10 mg/l mL

Injection volume: 20 μL or 2 μL

Flow rate: 0.35 mL/minute

Measurement temperature: 40° C.

### [Production of Acenaphthylene Polymers Y1 and Y2]

An azo-based polymerization initiator (2,2′-azobis(2,4,4-trimethylpentane)) was added to an unsubstituted acenaphthylene monomer such that 5 parts by mass of the azo-based polymerization initiator was added relative to 100 parts by mass of a solid fraction amount of the unsubstituted acenaphthylene monomer, and the obtained mixture were diluted with toluene to obtain a solution such that the solid fraction became 30% by mass. The solution was heated at 110° C. for 15 hours under a nitrogen atmosphere to fabricate acenaphthylene polymer Y1, which is a homopolymer of acenaphthylene.

The obtained acenaphthylene polymer Y1 had a number average molecular weight (Mn) of 5,300 and a weight average molecular weight (Mw) of 18,000.

The NMR measurement of the obtained resin revealed that a peak around 7.1 ppm derived from an acenaphthylene monomer had disappeared.

Acenaphthylene polymer Y2 was produced by means of the same method as that for producing the acenaphthylene polymer Y1, except that the amount of an azo-based polymerization initiator added to 100 parts by mass of a solid fraction amount of an unsubstituted acenaphthylene monomer in the method for producing the acenaphthylene polymer Y1, was changed to 1 part by mass. The obtained acenaphthylene polymer Y2 had a number average molecular weight (Mn) of 28,000 and a weight average molecular weight (Mw) of 140,000.

The number average molecular weight (Mn) and the weight average molecular weight (Mw) were obtained through measurement by gel permeation chromatography (GPC), and conversion with the use of a calibration curve of standard polystyrene. The calibration curve was approximated by a cubic equation using standard polystyrene: TSKstandard POLYSTYRENE (Type; A-2500, A-5000, F-20, and F-80) (manufactured by Tosoh Corporation, product name). The measurement conditions of GPC are as described above.

### [Production of Resin Composition]

Resin compositions (varnishes) of Examples 1 to 3, and Comparative Examples 1 and 2, having a solid content concentration of about 75% by mass were prepared by stirring and mixing each component shown in Table 1 with toluene at 25° C. in accordance with the blend amounts shown in Table 1. In Table 1, a unit of the blend amount of each component is expressed in parts by mass, and when a component is a solution, a unit is parts by mass in terms of the solid fraction equivalent. For the inorganic filler, Table 1 also shows a value in vol % relative to the solid fraction amount (100 vol %) of a composition.

The details of each material shown in Table 1 are as follows.

Vinylbenzyl compound X: Produced as above

Acenaphthylene polymer Y1: Produced as above

Acenaphthylene polymer Y2: Produced as above

Flame retardant: Phosphorus-based flame retardant

Inorganic filler: Silica (average particle size: 1 μm)

### [Fabrication of Prepreg]

The resin composition (varnish) obtained as described above was impregnated and coated on an NE glass cloth (manufactured by Nitto Boseki Co., Ltd.) having a thickness of 0.03 mm, and they were heated and dried at 130° C. for ten minutes to obtain a prepreg. In a prepreg of Comparative Example 1, the solid fraction amount derived from a resin composition was 91% by mass relative to the prepreg. In each of prepregs of Examples 1 and 2, the solid fraction amount derived from a resin composition was 90% by mass relative to each prepreg. In prepregs of Comparative Example 2 and Example 3, the solid fraction amounts derived from resin compositions were 81% by mass and 77% by mass, respectively relative to the prepregs.

### [Fabrication of Double-Sided Copper-Clad Laminate]

Electrolytic copper foils with athickness of 18 μm (“SI-VSP-AM-3R” (produce name), manufactured by MITSUI MINING & SMELTING CO., LTD.) were layered on both sides of the prepreg obtained as described above, such that matte surfaces of the foils face the prepreg. They were heated and pressure was applied thereto at 230° C. for 120 minutes under a vacuum pressing condition of 2 MPa to fabricate a double-sided copper-clad laminate.

### [Evaluation Method and Measurement Method]

Evaluation and measurement were performed as follows.

### <Sublimabilities of Acenaphthylene Monomer and Acenaphthylene Polymer Y1>

The temperature of an acenaphthylene monomer used for the production of the acenaphthylene polymer Y1 and a solid material of the acenaphthylene polymer Y1 was raised to a temperature in a range from 30° C. to 1000° C. at 20° C./min under a nitrogen atmosphere using TG-DTA (manufactured by Hitachi High-Tech Corporation, device name: STA7200), and a thermogravimetric loss behavior was evaluated. The evaluation criteria of the sublimability were as follows: when the 5% by mass weight loss temperature (Td5) was lower than 200° C., it was evaluated as having sublimability, and when the Td5 was 200° C. or higher, it was evaluated as not having sublimability.

The acenaphthylene monomer was evaluated as having sublimability because of having the Td5 of 140° C. Meanwhile, the acenaphthylene polymer Y1 was evaluated as having no sublimability because of having the Td5 of 380° C.

### <Dielectric Properties (Dielectric Constant (Dk) and Dielectric Loss Tangent (Df)>

The double-sided copper-clad laminate obtained as described above was immersed in an ammonium persulfate solution (10% by mass) (manufactured by MITSUBISHI GAS CHEMICAL COMPANY, INC.), which is a copper etching solution, to remove a copper foil. An evaluation substrate of 60 mm×100 mm was cut out from the substrate from which the copper foil had been removed.

After the evaluation substrate was dried at 105° C. for one hour, the evaluation substrate was placed in a stationary position for 24 hours, and measurement was performed as described below.

The dielectric constant (Dk) and the dielectric loss tangent (Df) were measured at 25° C. in 10 GHz bands using the evaluation substrate in accordance with an SPDR method (split post dielectric resonator). A “PNA Network Analyzer N5227A” (product name) by Agilent Technologies, Inc. was used as a measuring device. Table 1 shows results.

### <Flame Retardancy>

A flammability test was performed using the double-sided copper-clad laminate obtained as described above.

The double-sided copper-clad laminate was immersed in an ammonium persulfate solution (10% by mass) (manufactured by MITSUBISHI GAS CHEMICAL COMPANY, INC.), which was a copper etching solution, to remove a copper foil. An evaluation substrate of 13 mm×125 mm was cut out from the substrate from which the copper foil had been removed.

In accordance with the Vertical Burning Test (UL94-V), an upper end of the evaluation substrate was held, and a flame of a gas burner was applied to a lower end of the evaluation substrate vertically for ten seconds. After moving the gas burner away, if the substrate flame extinguished, the flame of the gas burner was further applied to the substrate immediately for another 10 seconds, and then the flame was moved away. The average combustion time after moving away the flame was calculated. In the Vertical Burning Test, evaluation was performed at N=5 per test number.

The “percentage of average combustion time relative to comparative example” in Table 1 shows the percentages (%) of the average combustion time of Examples 1 and 2 when the average combustion time of Comparative Example 1 without an acenaphthylene polymer was set at 100%, and the percentage (%) of the average combustion time of Example 3, when the average combustion time of Comparative Example 2 without an acenaphthylene polymer was set at 100%.

TABLE 1

| | Comparative | Example | Example | Comparative | Example |
|---|---|---|---|---|---|
| | Example 1 | 1 | 2 | Example 2 | 3 |
| Vinylbenzyl compound X | 34.3 | 30.4 | 26.7 | 29.6 | 21.0 |
| (unit: parts by mass) | | | | | |
| Acenaphthylene polymer Y1 | 0 | 3.4 | 6.7 | 0 | 0 |
| (unit: parts by mass) | | | | | |
| Acenaphthylene polymer Y2 | 0 | 0 | 0 | 0 | 7.0 |
| (unit: parts by mass) | | | | | |
| Flame retardant (unit: parts by | 11.2 | 11.0 | 10.9 | 1.3 | 1.2 |
| mass) | | | | | |
| Inorganic filler (unit: parts by | 54.5 | 55.2 | 55.7 | 69.1 | 70.8 |
| mass) | | | | | |
| Inorganic filler (unit: vol % | 40 | 40 | 40 | 55 | 55 |
| relative to total solid fraction | | | | | |
| of resin composition) | | | | | |

Evaluation results

| | | | | | |
|---|---|---|---|---|---|
| Dielectric constant (Dk) | 3.0 | 3.1 | 3.1 | 3.3 | 3.3 |
| Dielectric loss tangent (Df) | 0.00106 | 0.00102 | 0.00102 | 0.00122 | 0.00111 |
| Percentage of average | 100% | 93% | 50% | 100% | 26% |
| combustion time relative to | | | | | |
| comparative example | | | | | |

As described above, the acenaphthylene polymer Y1 was determiined as not having sublimability. Further, as shown in Table 1, in the evaluation of flame retardancy, all of Examples i to 3, in which the acenaphthylene polymer Y1 or Y2 is used, have smaller percentages of the average combustion time compared to those in corresponding comparative examples, and thus it is shown that Examples 1 to 3 have shorter average combustion time compared to the average combustion time of the corresponding comparative examples, and have favorable flame retardancy. Further, Examples 1 to 3 showed favorable dielectric properties.

### REFERENCE SIGNS LIST

1 Metal-clad metal foil
2 Cured product of prepreg
10 Metal-clad laminate

1. A resin composition comprising:
an (A) thermosetting resin; and
a (B) acenaphthylene polymer with a number average molecular weight of 1,000 or more.

2. The resin composition according to claim 1, wherein
an amount of the (B) acenaphthylene polymer with a number average molecular weight of 1,000 or more is 5% by mass or more, relative to a total amount of the (A) thermosetting resin and the (B) acenaphthylene polymer with a number average molecular weight of 1,000 or more.

3. The resin composition according to claim 1, wherein
the (A) thermosetting resin includes a compound with a vinylbenzyl group.

4. A prepreg formed using the resin composition according to any one of claim 1.

5. A resin film formed using the resin composition according to any one of claim 1.

6. A metal-clad laminate comprising:
a metal foil; and
a cured product of the resin composition according to any one of claim 1.

7. A metal-clad laminate formed using the prepreg according to claim 4 and a metal foil.

8. A printed wiring board comprising:
a cured product of the resin composition according to any one of claim 1.

9. A semiconductor package comprising:
the printed wiring board according to claim 8; and
a semiconductor element.

10. An acenaphthylene homopolymer having a number average molecular weight of 1,000 or more.
